(19) United States
(12) Patent Application Publication
(10) Pub. No.: US 2012/0057300 A1
(43) Pub. Date: Mar. 8, 2012

(54) HEAT DISSIPATION APPARATUS

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/886,547

(22) Filed: Sep. 20, 2010

(30) Foreign Application Priority Data
Sep. 7, 2010 (TW) 99130247

(51) Int. Cl. H05K 7/20

(52) U.S. Cl. 361/697; 361/704

(57) ABSTRACT

A heat dissipation apparatus includes a conductive board, a heat sink, and a thermo-electric cooler (TEC). The heat sink is mounted on the conductive board. The heat sink includes a base board defining a groove in a bottom of the base board. The TEC is accommodated in the groove, and a cooling surface of the TEC is coplanar with a bottom surface of the base board. A first part of the conductive board contacts the bottom surface of the base board. A second part of the conductive board contacts the cooling surface of the TEC.

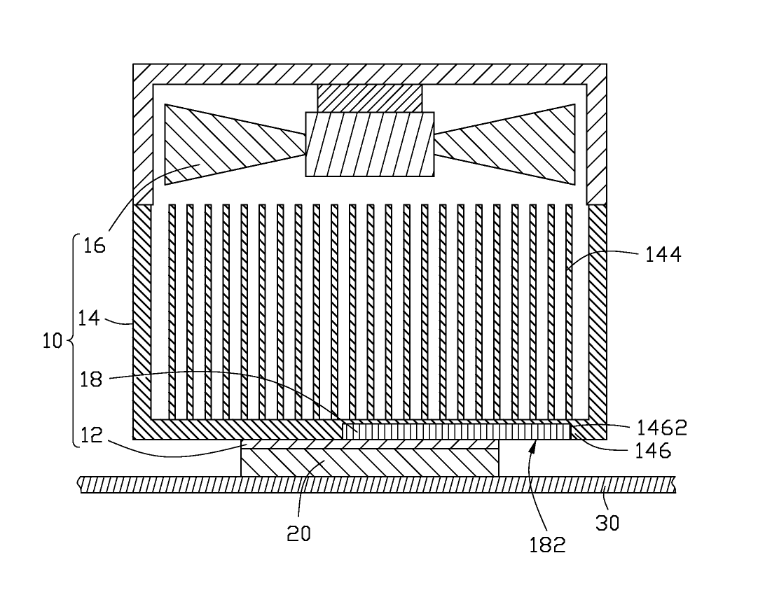

### BACKGROUND

1. Technical Field

The present disclosure relates to a heat dissipation apparatus.

2. Description of Related Art

Nowadays, in electronic devices, there is a lot of heat generated by elements needed to be dissipated. For example, a heat dissipation apparatus is mounted on a central processing unit (CPU) of a motherboard to dissipate heat generated by the CPU. A common heat dissipation apparatus includes a heat sink mounted on the CPU and a fan mounted on the heat sink. The heat sink absorbs heat generated by the CPU, and then the fan blows air around the heat sink to further dissipate the heat. However, sometimes, this common heat dissipation apparatus cannot satisfy heat dissipation requirements.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

The figure is a schematic, sectional view of an embodiment of a heat dissipation apparatus, together with a central processing unit and a motherboard.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the figure, an embodiment of a heat dissipation apparatus 10 used to dissipate heat generated by an electronic device, such as a central processing unit (CPU) 20 mounted on a motherboard 30, includes a conductive board 12, a heat sink 14, a fan 16, and a thermo-electric cooler (TEC) 18. The heat sink 14 includes a base board 146 and a number of fins 144 substantially perpendicularly extending up from the base board 146.

The bottom of the base board 146 defines a groove 1462, opposite to the fins 144. The TEC 18 is accommodated in the groove 1462, with a cooling surface 182 of the TEC 18 being coplanar with the bottom surface of the base board 146. The TEC 18 also includes other elements, such as a power cable. These other elements fall within well-known technologies, and are therefore not described here.

The top surface of the CPU 20 contacts the bottom surface of the conductive board 12. A first part of the top surface of the conductive board 12 contacts the bottom surface of the base board 146. A second part of the top surface of the conductive board 12 contacts the cooling surface 182 of the TEC 18. The fan 16 is mounted on the fins 144 of the heat sink 14. In one embodiment, the areas of the two parts of the top surface of the conductive board 12 are the same.

In use, the conductive board 12 transfers heat generated by the CPU 20 to the heat sink 14 and the TEC 18. The base board 146 absorbs heat from the conductive board 12 to the fins 144, and then the fan 16 dissipates the heat of the heat sink 14 to outside. Meanwhile, the TEC 18 further cools the conductive board 12 when the TEC 18 is powered. Therefore, heat generated by the CPU 20 can be dissipated by two modes at the same time, one mode uses the heat sink 14 and the other mode further uses the TEC 18, which increases heat dissipation efficiency.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A heat dissipation apparatus used to dissipate heat generated by an electronic device, the heat dissipation apparatus comprising:
a conductive board mounted on the electronic device;
a heat sink mounted on the conductive board opposite to the electronic device, wherein the heat sink comprises a base board defining a groove in a bottom of the base board; and
a thermo-electric cooler (TEC) accommodated in the groove, wherein a cooling surface of the TEC is coplanar with a bottom surface of the base board;
wherein a first part of the conductive board contacts the bottom surface of the base board, and a second part of the conductive board contacts the cooling surface of the TEC.

2. The heat dissipation apparatus of claim 1, further comprising a fan mounted on the heat sink.

3. The heat dissipation apparatus of claim 1, wherein the heat sink further comprises a plurality of fins substantially perpendicularly extending from the base board, opposite to the groove.

4. The heat dissipation apparatus of claim 1, wherein the areas of the first and second parts of the conductive board are the same.
